(19) United States
(12) Patent Application Publication
(10) Pub. No.: US 2026/0142125 A1
(43) Pub. Date: May 21, 2026

(54) PLASMA PROCESSING APPARATUS

(71) Applicant: Tokyo Electron Limited, Tokyo (JP)

(72) Inventor: Naoki MATSUMOTO, Kurokawa-gun (JP)

(21) Appl. No.: 19/406,296

(22) Filed: Dec. 2, 2025

Related U.S. Application Data
(63) Continuation of application No. PCT/JP2024/005998, filed on Feb. 20, 2024.

(30) Foreign Application Priority Data
Jun. 14, 2023 (JP) 2023-097593

(51) Int. Cl. H01J 37/32

(52) U.S. Cl. CPC H01J 37/32174; H01J 37/32183; H01J 37/32568; H01J 37/32577; H01J 37/32642; H01J 37/32715; H01J 2237/334

(57) ABSTRACT

A plasma processing apparatus includes a plasma processing chamber, a variable impedance element, a substrate support, and at least one voltage pulse generator. The substrate support is located in the plasma processing chamber. The substrate support includes a conductive base, an electrostatic chuck, an edge ring, a substrate bias electrode, a ring bias electrode, an additional electrode electrically coupled to a ground potential through the variable impedance element, and at least one connector electrically coupling the edge ring and the conductive base. The at least one voltage pulse generator is electrically coupled to the substrate bias electrode and the ring bias electrode to generate a pulsed voltage signal.

### CROSS-REFERENCE TO RELATED APPLICATIONS

The present application is based on International Application No. PCT/JP2024/005998, filed on Feb. 20, 2024, which claims benefit to Japanese Patent Application No. 2023-097593, filed on Jun. 14, 2023, the entire content of which is incorporated herein by reference.

### BACKGROUND

### Field

Exemplary embodiments of the present disclosure relate to a plasma processing apparatus.

### Description of Related Art

Patent Literature 1 describes a technique for a variable impedance circuit located on a second electrical path for feeding power from a matching circuit to an edge ring. Patent Literature 2 describes a technique for a variable capacitor connected to a wire connecting an annular electrode and a conductive base.

### CITATION LIST

### Patent Literature

Patent Literature 1: Japanese Unexamined Patent Application Publication No. 2020-96176
Patent Literature 2: U.S. Patent Application Publication No. 2019/0006155

### SUMMARY

A plasma processing apparatus according to one exemplary embodiment of the present disclosure includes a plasma processing chamber, a variable impedance element, a substrate support, and at least one voltage pulse generator. The substrate support is located in the plasma processing chamber. The substrate support includes a conductive base, an electrostatic chuck located on the conductive base and having a substrate support surface and a ring support surface, an edge ring located on the ring support surface to surround a substrate on the substrate support surface, a substrate bias electrode located below the substrate support surface inside the electrostatic chuck, a ring bias electrode located below the ring support surface inside the electrostatic chuck, an additional electrode located between the ring support surface and the ring bias electrode inside the electrostatic chuck and electrically coupled to a ground potential through the variable impedance element, and at least one connector electrically coupling the edge ring and the conductive base. The at least one voltage pulse generator is electrically coupled to the substrate bias electrode and the ring bias electrode to generate a pulsed voltage signal.

### BRIEF DESCRIPTION OF DRAWINGS

FIG. 1 is a diagram of a plasma processing system, illustrating an example structure.

FIG. 2 is a diagram of a plasma processing apparatus, illustrating an example structure.

FIG. 3 is a diagram of a substrate support and an electrical circuit, illustrating example structures.

FIG. 4 is a diagram of a connector, illustrating an example structure.

FIG. 5 is a graph showing an example pulsed voltage signal.

FIG. 6 is a diagram of a substrate support and an electrical circuit, illustrating other example structures.

FIG. 7 is a diagram of a substrate support and an electrical circuit, illustrating other example structures.

FIG. 8 is a diagram of a substrate support and an electrical circuit, illustrating other example structures.

FIG. 9 is a diagram of a substrate support and an electrical circuit, illustrating other example structures.

### DETAILED DESCRIPTION

One or more embodiments of the present disclosure will be described below.

A plasma processing apparatus according to one exemplary embodiment includes a plasma processing chamber, a variable impedance element, a substrate support, and at least one voltage pulse generator. The substrate support is located in the plasma processing chamber. The substrate support includes a conductive base, an electrostatic chuck located on the conductive base and having a substrate support surface and a ring support surface, an edge ring located on the ring support surface to surround a substrate on the substrate support surface, a substrate bias electrode located below the substrate support surface inside the electrostatic chuck, a ring bias electrode located below the ring support surface inside the electrostatic chuck, an additional electrode located between the ring support surface and the ring bias electrode inside the electrostatic chuck and electrically coupled to a ground potential through the variable impedance element, and at least one connector electrically coupling the edge ring and the conductive base. The at least one voltage pulse generator is electrically coupled to the substrate bias electrode and the ring bias electrode to generate a pulsed voltage signal.

In one exemplary embodiment, the at least one voltage pulse generator is electrically coupled to the substrate bias electrode and the ring bias electrode through the conductive base.

In one exemplary embodiment, the at least one voltage pulse generator includes a first voltage pulse generator electrically coupled to the substrate bias electrode to generate a first pulsed voltage signal, and a second voltage pulse generator electrically coupled to the ring bias electrode to generate a second pulsed voltage signal.

In one exemplary embodiment, the substrate support includes a substrate chuck electrode. The substrate chuck electrode is located between the substrate bias electrode and the substrate support surface inside the electrostatic chuck.

In one exemplary embodiment, the substrate support includes a ring chuck electrode. The ring chuck electrode is located between the ring support surface and the additional electrode inside the electrostatic chuck.

A plasma processing apparatus according to one exemplary embodiment includes a plasma processing chamber, a variable impedance element, a substrate support, and at least one radio-frequency generator. The substrate support is located in the plasma processing chamber. The substrate support includes a conductive base, an electrostatic chuck located on the conductive base and having a substrate support surface and a ring support surface, an edge ring located on the ring support surface to surround a substrate on the substrate support surface, a substrate bias electrode located below the substrate support surface inside the electrostatic chuck, a ring bias electrode located below the ring support surface inside the electrostatic chuck, an additional electrode located between the ring support surface and the ring bias electrode inside the electrostatic chuck and electrically coupled to a ground potential through the variable impedance element, and at least one connector electrically coupling the edge ring and the conductive base. The at least one radio-frequency generator is electrically coupled to the substrate bias electrode and the ring bias electrode to generate a radio-frequency signal.

In one exemplary embodiment, the at least one radio-frequency generator is electrically coupled to the substrate bias electrode and the ring bias electrode through the conductive base.

In one exemplary embodiment, the at least one radio-frequency generator includes a first radio-frequency generator electrically coupled to the substrate bias electrode, and a second radio-frequency generator electrically coupled to the ring bias electrode.

In one exemplary embodiment, the substrate support includes a substrate chuck electrode. The substrate chuck electrode is located between the substrate bias electrode and the substrate support surface inside the electrostatic chuck.

In one exemplary embodiment, the substrate support includes a ring chuck electrode. The ring chuck electrode is located between the ring support surface and the additional electrode inside the electrostatic chuck.

One or more embodiments of the present disclosure will now be described with reference to the drawings. In the drawings, like reference numerals denote the same or like components. Such components will not be described repeatedly. Unless otherwise specified, the positional relationships shown in the drawings are used to describe the vertical, lateral, and other positions. The drawings are not drawn to scale relative to the actual ratio of each component, and the actual ratio is not limited to the ratio in the drawings.

### Example of Plasma Processing System

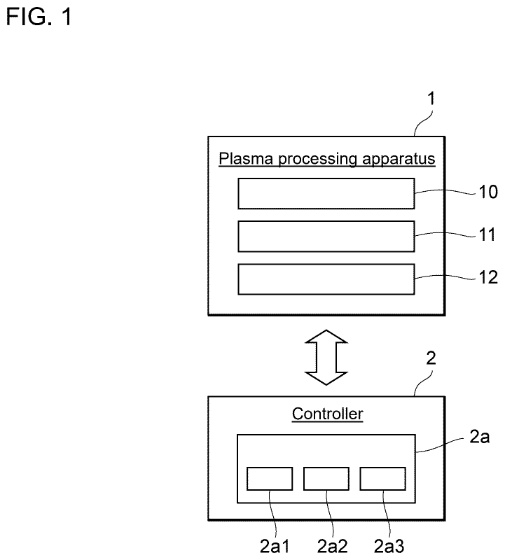

FIG. 1 is a diagram of a plasma processing system, illustrating an example structure. In one embodiment, the plasma processing system includes a plasma processing apparatus 1 and a controller 2. The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 also has at least one gas inlet for supplying at least one process gas into the plasma processing space and at least one gas outlet for discharging the gas from the plasma processing space. The gas inlet is connected to a gas supply 20 (described later). The gas outlet is connected to an exhaust system 40 (described later). The substrate support 11 is located in the plasma processing space and has a substrate support surface for supporting a substrate.

The plasma generator 12 generates plasma from at least one process gas supplied into the plasma processing space. The plasma generated in the plasma processing space may be, for example, capacitively coupled plasma (CCP), inductively coupled plasma (ICP), electron cyclotron resonance (ECR) plasma, helicon wave plasma (HWP), or surface wave plasma (SWP). The plasma generator 12 may be one of various plasma generators including an alternating current (AC) plasma generator and a direct current (DC) plasma generator. In one embodiment, an AC signal (AC power) used in the AC plasma generator has a frequency in a range of 100 kHz to 10 GHz. Thus, the AC signal may be a radio-frequency (RF) signal or a microwave signal. In one embodiment, the RF signal has a frequency in a range of 100 kHz to 150 MHz.

The controller 2 processes computer-executable instructions that cause the plasma processing apparatus 1 to perform various steps described in one or more embodiments of the present disclosure. The controller 2 may control the components of the plasma processing apparatus 1 to perform the various steps described herein. In one embodiment, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2a1 may perform various control operations by loading a program from the storage 2a2 and executing the loaded program. The program may be prestored in the storage 2a2 or may be obtained through a medium as appropriate. The obtained program is stored into the storage 2a2 to be loaded from the storage 2a2 and executed by the processor 2a1. The medium may be one of various storage media readable by the computer 2a or a communication line connected to the communication interface 2a3. The processor 2a1 may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN).

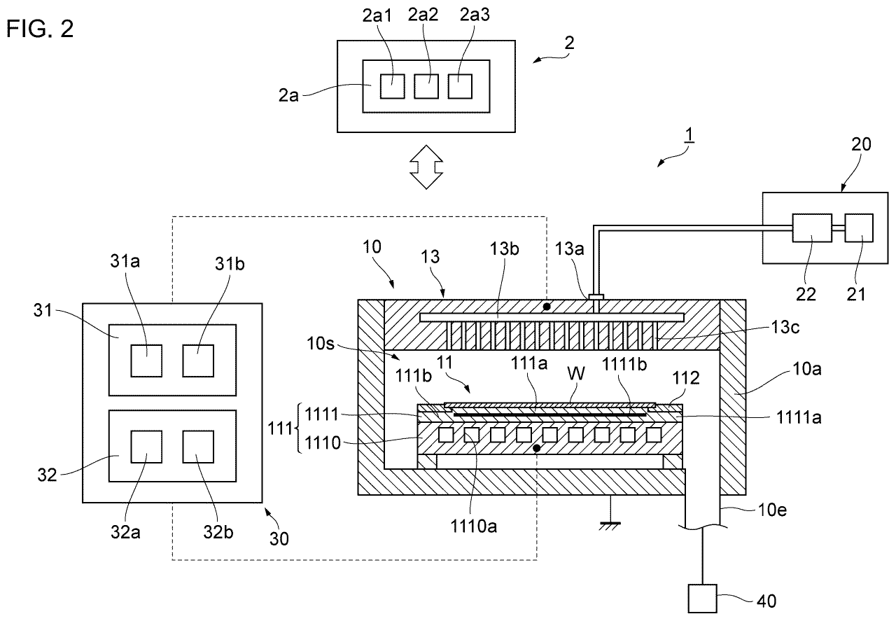

An example structure of a capacitively coupled plasma processing apparatus as an example of the plasma processing apparatus 1 will now be described. FIG. 2 is a diagram of the capacitively coupled plasma processing apparatus 1, illustrating an example structure.

The capacitively coupled plasma processing apparatus 1 includes the plasma processing chamber 10 (also simply referred to as a chamber), the gas supply 20, a power supply 30, and the exhaust system 40. The plasma processing apparatus 1 further includes the substrate support 11 and a gas guide unit. The gas guide unit allows at least one process gas to be introduced into the plasma processing chamber 10. The gas guide unit includes a showerhead 13. The substrate support 11 is located in the plasma processing chamber 10. The showerhead 13 is located above the substrate support 11. In one embodiment, the showerhead 13 defines at least a part of the ceiling of the plasma processing chamber 10. The plasma processing chamber 10 has a plasma processing space 10s defined by the showerhead 13, a sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 includes a central portion 111a for supporting a substrate W and an annular portion 111b for supporting the ring assembly 112. A wafer is an example of the substrate W. The annular portion 111b of the body 111 surrounds the central portion 111a of the body 111 as viewed in plan. The substrate W is placeable on the central portion 111a of the body 111. The ring assembly 112 is located on the annular portion 111b of the body 111 to surround the substrate W on the central portion 111a of the body 111. Thus, the central portion 111a is also referred to as a substrate support surface for supporting the substrate W. The annular portion 111b is also referred to as a ring support surface for supporting the ring assembly 112.

In one embodiment, the body 111 includes a base 1110 (also referred to as a conductive base) and an electrostatic chuck (ESC) 1111. The base 1110 includes a conductive member. The conductive member in the base 1110 may function as a lower electrode. The ESC 1111 is located on the base 1110. The ESC 1111 includes a ceramic member 1111a and an electrostatic electrode 1111b located inside the ceramic member 1111a. The ceramic member 1111a includes the central portion 111a. In one embodiment, the ceramic member 1111a also includes the annular portion 111b. The annular portion 111b may be included in another member surrounding the ESC 1111, such as an annular ESC or an annular insulating member. In this case, the ring assembly 112 may be located on the annular ESC or the annular insulating member, or may be located on both the ESC 1111 and the annular insulating member. At least one RF/DC electrode coupled to an RF power supply 31 or a DC power supply 32, or both (described later) may be located inside the ceramic member 1111a. In this case, the RF/DC electrode functions as a lower electrode. When a bias RF signal or a DC signal, or both (described later) are provided to at least one RF/DC electrode, the RF/DC electrode is also referred to as a bias electrode. The conductive member in the base 1110 and at least one RF/DC electrode may function as multiple lower electrodes. The electrostatic electrode 1111b may also function as a lower electrode. The substrate support 11 thus includes at least one lower electrode.

The ring assembly 112 includes one or more annular members. In one embodiment, the one or more annular members include one or more edge rings and at least one cover ring. The edge rings are formed from a conductive material or an insulating material. The cover ring is formed from an insulating material.

The substrate support 11 may include a temperature controller that adjusts the temperature of at least one of the ESC 1111, the ring assembly 112, or the substrate to a target temperature. The temperature controller may include a heater, a heat transfer medium, a channel 1110a, or a combination of these. The channel 1110a carries a heat transfer fluid such as brine or a gas. In one embodiment, the channel 1110a is defined inside the base 1110, and one or more heaters are located inside the ceramic member 1111a in the ESC 1111. The substrate support 11 may include a heat transfer gas supply to supply a heat transfer gas into a space between the back surface of the substrate W and the central portion 111a.

The showerhead 13 introduces at least one process gas from the gas supply 20 into the plasma processing space 10s. The showerhead 13 includes at least one gas inlet 13a, at least one gas-diffusion compartment 13b, and multiple gas guides 13c. The process gas supplied to the gas inlet 13a passes through the gas-diffusion compartment 13b and is introduced into the plasma processing space 10s through the multiple gas guides 13c. The showerhead 13 further includes at least one upper electrode. In addition to the showerhead 13, the gas guide unit may include one or more side gas injectors (SGIs) installed in one or more openings in the sidewall 10a.

The gas supply 20 may include at least one gas source 21 and at least one flow controller 22. In one embodiment, the gas supply 20 supplies at least one process gas from each gas source 21 to the showerhead 13 through the corresponding flow controller 22. The flow controller 22 may be, for example, a mass flow controller or a pressure-based flow controller. The gas supply 20 may further include at least one flow rate modulator that causes at least one process gas to be supplied at a modulated flow rate or in a pulsed manner.

The power supply 30 includes the RF power supply 31 coupled to the plasma processing chamber 10 through at least one impedance matching circuit. The RF power supply 31 provides at least one RF signal (RF power) to at least one lower electrode or at least one upper electrode, or both. This generates plasma from at least one process gas supplied into the plasma processing space 10s. The RF power supply 31 may thus function as at least a part of the plasma generator 12. A bias RF signal is provided to at least one lower electrode to generate a bias potential in the substrate W, thus drawing ion components in the generated plasma toward the substrate W.

In one embodiment, the RF power supply 31 includes a first RF generator 31a and a second RF generator 31b. The first RF generator 31a is coupled to at least one lower electrode or at least one upper electrode, or both through at least one impedance matching circuit to generate a source RF signal (source RF power) for plasma generation. In one embodiment, the source RF signal has a frequency in a range of 10 to 150 MHz. In one embodiment, the first RF generator 31 a may generate multiple source RF signals with different frequencies. The one or more generated source RF signals are provided to at least one lower electrode or at least one upper electrode, or both.

The second RF generator 31b is coupled to at least one lower electrode through at least one impedance matching circuit to generate a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The one or more generated bias RF signals are provided to at least one lower electrode. In various embodiments, at least one of the source RF signal or the bias RF signal may be pulsed.

The power supply 30 may include the DC power supply 32 coupled to the plasma processing chamber 10. The DC power supply 32 includes a first DC generator 32a and a second DC generator 32b. In one embodiment, the first DC generator 32a is coupled to at least one lower electrode to generate a first DC signal. The generated first DC signal is applied to at least one lower electrode. In one embodiment, the second DC generator 32b is coupled to at least one upper electrode to generate a second DC signal. The generated second DC signal is applied to at least one upper electrode.

In various embodiments, the first DC signal and the second DC signal may be pulsed. In this case, the sequence of voltage pulses is applied to at least one lower electrode or at least one upper electrode, or both. The voltage pulses may have rectangular, trapezoidal, or triangular pulse waveforms, or a combination of these. In one embodiment, a waveform generator for generating a sequence of voltage pulses based on DC signals is coupled between the first DC generator 32a and at least one lower electrode. Thus, the first DC generator 32a and the waveform generator form a voltage pulse generator. When the second DC generator 32b and the waveform generator form a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle. The power supply 30 may include the first DC generator 32a and the second DC generator 32b in addition to the RF power supply 31 or may include the first DC generator 32a in place of the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may be a turbomolecular pump, a dry pump, or a combination of these.

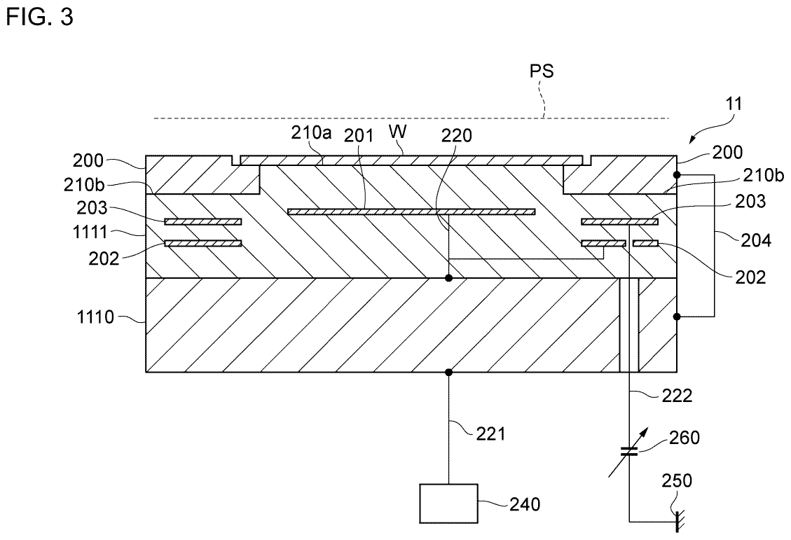

FIG. 3 is a diagram of the substrate support 11 and an electrical circuit in one embodiment, illustrating example structures. In one embodiment, the substrate support 11 may include the conductive base 1110, the ESC 1111, an edge ring 200, a substrate bias electrode 201, a ring bias electrode 202, an additional electrode 203, and a connector 204.

In one embodiment, the ESC 1111 may have, on its upper surface, a substrate support surface 210a and a ring support surface 210b surrounding the substrate support surface 210a. The substrate support surface 210a may be an example of the central portion 111a illustrated in FIG. 2. The ring support surface 210b may be an example of the annular portion 111b illustrated in FIG. 2.

As illustrated in FIG. 3, the edge ring 200 may be located on the ring support surface 210b to surround the substrate W on the substrate support surface 210a. The edge ring 200 may be conductive. The edge ring 200 may have an upper surface flush with or at a higher level than the upper surface of the substrate W located on the substrate support surface 210a. The edge ring 200 may be included in the ring assembly 112 illustrated in FIG. 2.

As illustrated in FIG. 3, the substrate bias electrode 201 may be located inside the ESC 1111. The substrate bias electrode 201 may be located below the substrate support surface 210a. The substrate bias electrode 201 may be electrically coupled to the conductive base 1110 through a first conductor 220. The substrate bias electrode 201 may be circular. The substrate bias electrode 201 may have its center aligned with the center of the ESC 1111 as viewed in plan.

The ring bias electrode 202 may be located inside the ESC 1111. The ring bias electrode 202 may be located below the ring support surface 210b. The ring bias electrode 202 may be electrically coupled to the conductive base 1110 through the first conductor 220. The ring bias electrode 202 may be annular. The ring bias electrode 202 may have its center aligned with the center of the ESC 1111 as viewed in plan.

The conductive base 1110 may be electrically coupled to at least one voltage pulse generator 240 through a second conductor 221. The voltage pulse generator 240 may generate a pulsed voltage signal. The pulsed voltage signal may include multiple voltage pulses. The voltage pulse generator 240 may be electrically coupled to the substrate bias electrode 201 and the ring bias electrode 202 through the second conductor 221, the conductive base 1110, and the first conductor 220. The voltage pulse generator 240 may be an example of the first DC generator 32a illustrated in FIG. 2.

As illustrated in FIG. 3, the additional electrode 203 may be located inside the ESC 1111. The additional electrode 203 may be located between the ring support surface 210b and the ring bias electrode 202. The additional electrode 203 may be electrically coupled to a ground potential 250 through a third conductor 222. The ground potential 250 may be located outside the chamber 10. The third conductor 222 may be electrically coupled to a variable impedance element 260. The impedance of the variable impedance element 260 may be adjusted to control the potential of the edge ring 200 during plasma generation. The impedance of the variable impedance element 260 may be controlled by the controller 2. The variable impedance element 260 may include a variable capacitor having a variable capacitance. The variable impedance element 260 may include at least one selected from the group consisting of a variable capacitor, a variable resistor, and a variable inductor. The additional electrode 203 may be electrically insulated from the conductive base 1110. The additional electrode 203 may be annular. The additional electrode 203 may have its center aligned with the center of the ESC 1111 as viewed in plan.

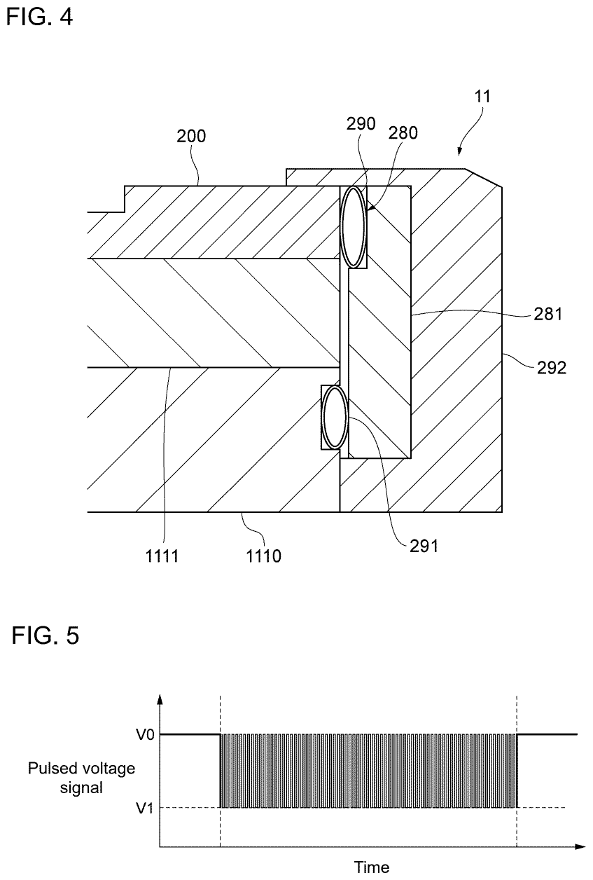

The connector 204 may electrically couple the edge ring 200 and the conductive base 1110. As illustrated in FIG. 4, the connector 204 may include at least one annular conductive spring 280 and an annular conductive member 281. The at least one annular conductive spring 280 may include a first annular conductive spring 290 and a second annular conductive spring 291. The first annular conductive spring 290 may be in contact with an outer wall of the edge ring 200. The second annular conductive spring 291 may be in contact with an outer wall of the conductive base 1110. The annular conductive member 281 may be located outside the edge ring 200, the ESC 1111, and the conductive base 1110. The annular conductive member 281 may be in contact with the first annular conductive spring 290 and the second annular conductive spring 291 and electrically couple the first annular conductive spring 290 and the second annular conductive spring 291. The annular conductive member 281 may press the first annular conductive spring 290 against the outer wall of the edge ring 200. The annular conductive member 281 may press the second annular conductive spring 291 against the outer wall of the conductive base 1110. The annular conductive member 281 may be electrically insulated from the ESC 1111. The annular conductive member 281 may be covered with an insulating annular member 292. The annular member 292 may hold the annular conductive member 281 to fix the annular conductive member 281 at a position outside the edge ring 200 and the conductive base 1110. One or more connectors 204 may be included.

### Example of Plasma Processing Method

In one embodiment, a plasma processing method includes etching a film on the substrate W with plasma. In one embodiment, the plasma processing method is implementable with the controller 2 in the plasma processing apparatus 1.

The substrate W is first loaded into the chamber 10 with a transfer arm, placed on the substrate support 11 with a lifter, and clamped on the substrate support 11 as illustrated in FIG. 2.

Subsequently, a process gas is supplied from the gas supply 20 to the showerhead 13 and then into the plasma processing space 10s from the showerhead 13. The supplied process gas contains a gas for generating an active species that is to be used for etching the substrate W.

The source RF signal is provided from the RF power supply 31 to the upper electrode or the lower electrode. The pulsed voltage signal is provided from the DC power supply 32 to the lower electrode. The atmosphere in the plasma processing space 10s is discharged through the gas outlet 10e to reduce the pressure in the plasma processing space 10s. This generates plasma from the process gas above the substrate support 11 in the plasma processing space 10s to etch the substrate W.

In one example of the above etching, the pulsed voltage signal may be provided from the voltage pulse generator 240 illustrated in FIG. 3 to the substrate bias electrode 201 and the ring bias electrode 202 during plasma generation. As illustrated in FIG. 5, the multiple voltage pulses included in the pulsed voltage signal may have a first voltage level V1 greater than a zero voltage level V0. The first voltage level V1 may be negative. The pulsed voltage signal may be provided from the voltage pulse generator 240 illustrated in FIG. 3 to the substrate bias electrode 201 and the ring bias electrode 202 through the second conductor 221, the conductive base 1110, and the first conductor 220. The pulsed voltage signal may carry a current to the ground potential 250 through the second conductor 221, the conductive base 1110, the connector 204, the edge ring 200, the additional electrode 203, and the third conductor 222. In this case, the impedance of the variable impedance element 260 may be adjusted to control the potential of the edge ring 200. The potential of the edge ring 200 may be controlled relative to the potential of the substrate W to allow a plasma sheath PS generated above the substrate W and the edge ring 200 to be substantially horizontal. Thus, ions of plasma may be supplied perpendicularly to the substrate W around the outer periphery of the substrate W. The tilt angle (the incident angle of ions with respect to the substrate W) may thus remain 90°.

The impedance of the variable impedance element 260 may be adjusted based on the amount of wear of the edge ring 200. The amount of wear of the edge ring 200 may be determined based on the total time of providing a pulsed voltage signal from the voltage pulse generator 240 to the conductive base 1110, or in other words, the operation time of the voltage pulse generator 240. The amount of wear of the edge ring 200 may be detected with a sensor. The edge ring 200 may have a lower potential as the amount of wear of the edge ring 200 increases. The impedance of the variable impedance element 260 may be adjusted before plasma is generated.

In the present exemplary embodiment, the plasma processing apparatus 1 includes the variable impedance element 260, the additional electrode 203, at least one connector 204, and at least one voltage pulse generator 240. The additional electrode 203 is located between the ring support surface 210b and the ring bias electrode 202 inside the ESC 1111 and electrically coupled to the ground potential 250 through the variable impedance element 260. The connector 204 electrically couples the edge ring 200 and the conductive base 1110. Thus, when the voltage pulse generator 240 provides a pulsed voltage signal to the substrate bias electrode 201 and the ring bias electrode 202, the potential of the edge ring 200 is adjustable by adjusting the impedance of the variable impedance element 260. This allows the potential of the edge ring 200 to be adjusted based on the amount of wear of the edge ring 200 and the plasma sheath PS generated above the substrate W and the edge ring 200 to remain horizontal. Thus, the tilt angle (the incident angle of ions with respect to the substrate W) around the outer periphery of the substrate W can remain 90°.

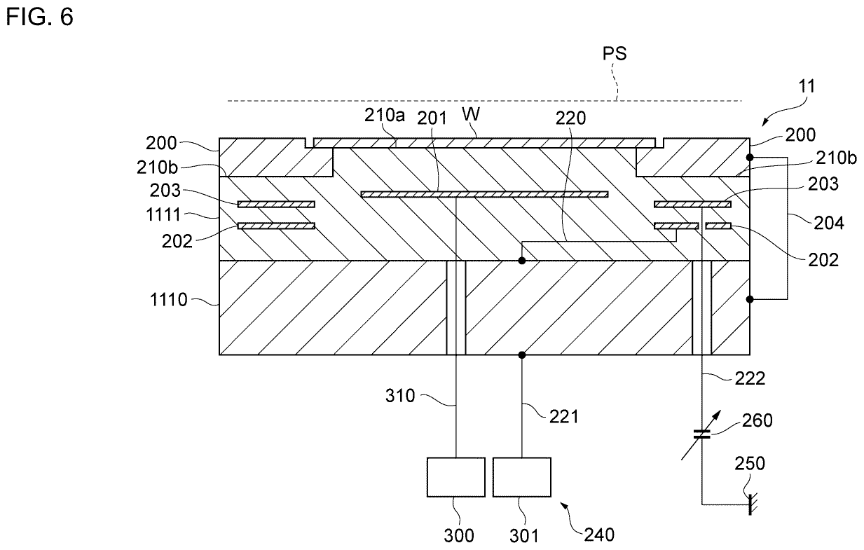

In the above embodiments, as illustrated in FIG. 6, at least one voltage pulse generator 240 may include a first voltage pulse generator 300 and a second voltage pulse generator 301. The first voltage pulse generator 300 may be electrically coupled to the substrate bias electrode 201 to generate a first pulsed voltage signal. The second voltage pulse generator 301 may be electrically coupled to the ring bias electrode 202 to generate a second pulsed voltage signal. The first voltage pulse generator 300 may be electrically coupled to the substrate bias electrode 201 through a fourth conductor 310 without through the conductive base 1110. The second voltage pulse generator 301 may be electrically coupled to the ring bias electrode 202 through the second conductor 221, the conductive base 1110, and the first conductor 220. During plasma processing, the first voltage pulse generator 300 may provide the first pulsed voltage signal to the substrate bias electrode 201, and the second voltage pulse generator 301 may provide the second pulsed voltage signal to the ring bias electrode 202.

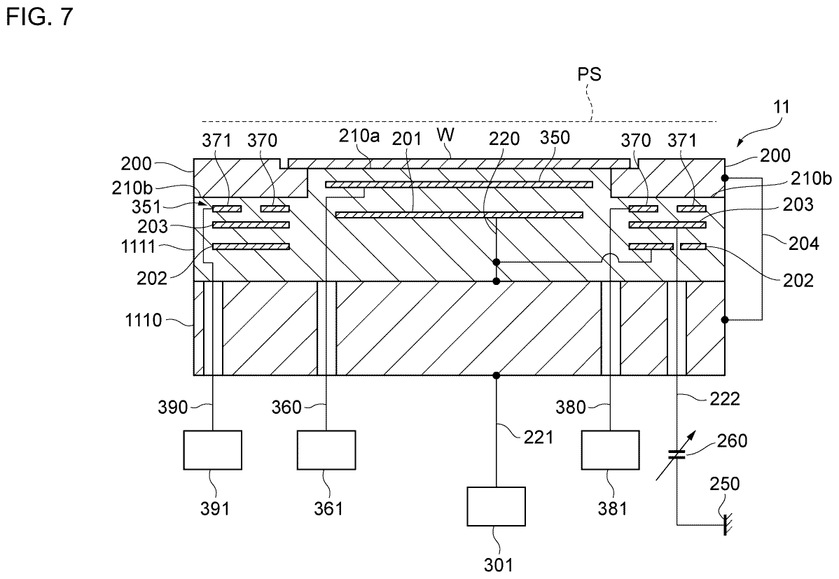

In the above embodiments, as illustrated in FIG. 7, the substrate support 11 may further include at least one substrate chuck electrode 350 and at least one ring chuck electrode 351.

The substrate chuck electrode 350 may be located between the substrate support surface 210a and the substrate bias electrode 201 inside the ESC 1111. The substrate chuck electrode 350 may be electrically coupled to a DC power supply 361 through a fifth conductor 360. The fifth conductor 360 may be electrically coupled to a filter that reduces an RF signal or a pulsed voltage signal entering the DC power supply 361. The fifth conductor 360 may be electrically insulated from the conductive base 1110. The DC power supply 361 applies a DC voltage to the substrate chuck electrode 350 to generate an electrostatic attraction (Coulomb force) between the substrate chuck electrode 350 and the substrate W. The substrate W may be attracted by the ESC 1111 under the electrostatic attraction and clamped on the substrate support surface 210a. The substrate chuck electrode 350 may include multiple substrate chuck electrodes. The substrate chuck electrode 350 may be an example of the electrostatic electrode 1111b illustrated in FIG. 2.

As illustrated in FIG. 7, the at least one ring chuck electrode 351 may be located between the ring support surface 210b and the additional electrode 203 inside the ESC 1111. The ring chuck electrode 351 may include an inner chuck electrode 370 and an outer chuck electrode 371.

The inner chuck electrode 370 and the outer chuck electrode 371 may be annular. The inner chuck electrode 370 may have its center aligned with the center of the outer chuck electrode 371 as viewed in plan. The inner chuck electrode 370 and the outer chuck electrode 371 may be located at the same position in the vertical direction.

The inner chuck electrode 370 may be electrically coupled to a DC power supply 381 through a sixth conductor 380. The outer chuck electrode 371 may be electrically coupled to a DC power supply 391 through a seventh conductor 390. The ring chuck electrode 351 may have a potential difference that is set between the inner chuck electrode 370 and the outer chuck electrode 371. The potential difference may cause the edge ring 200 to be clamped on the ring support surface 210b. The sixth conductor 380 and the seventh conductor 390 may each be electrically coupled to a filter that reduces an RF signal or a pulsed voltage signal entering the corresponding DC power supply 381 or 391. The sixth conductor 380 and the seventh conductor 390 may be electrically insulated from the conductive base 1110. The ring chuck electrode 351 may include a single chuck electrode or three or more chuck electrodes.

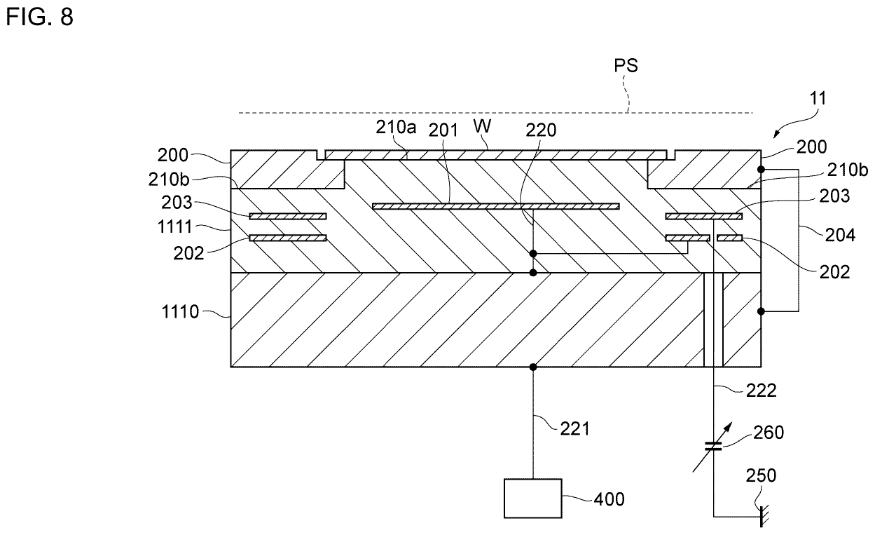

In the above embodiments, as illustrated in FIG. 8, the plasma processing apparatus 1 may include at least one RF generator 400 in place of the voltage pulse generator 240. The other components may be the same as those of the substrate support 11 and the electrical circuit illustrated in FIG. 3.

As illustrated in FIG. 8, the at least one RF generator 400 may be electrically coupled to the substrate bias electrode 201 and the ring bias electrode 202 through the second conductor 221, the conductive base 1110, and the first conductor 220. The RF generator 400 may generate an RF signal. The RF generator 400 may generate a bias RF signal. The bias RF signal may have a frequency in a range of 100 kHz to 60 MHz. The RF generator 400 may generate a source RF signal for plasma generation. The source RF signal may have a frequency in a range of 10 to 150 MHz. The RF generator 400 may be an example of the second RF generator 31b illustrated in FIG. 2.

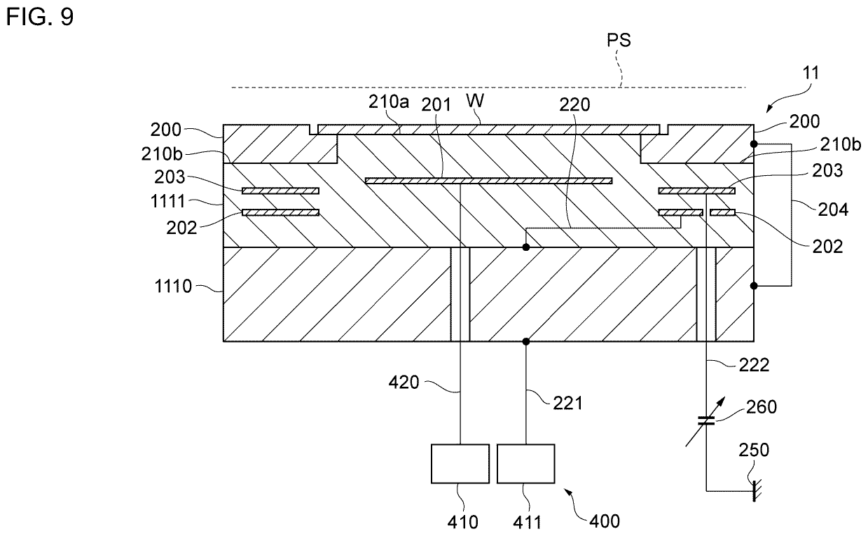

As illustrated in FIG. 9, the at least one RF generator 400 may include a first RF generator 410 electrically coupled to the substrate bias electrode 201 and a second RF generator 411 electrically coupled to the ring bias electrode 202. The first RF generator 410 may be electrically coupled to the substrate bias electrode 201 through an eighth conductor 420 without through the conductive base 1110. The second RF generator 411 may be electrically coupled to the ring bias electrode 202 through the second conductor 221, the conductive base 1110, and the first conductor 220. During plasma processing, the first RF generator 410 may provide a first RF signal to the substrate bias electrode 201, and the second RF generator 411 may provide a second RF signal to the ring bias electrode 202.

The plasma processing apparatus 1 may include both the voltage pulse generator 240 and the RF generator 400 described above.

Although the capacitively coupled plasma processing apparatus is used in the above embodiments, the technique may be applicable to another plasma processing apparatus. For example, the capacitively coupled plasma processing apparatus may be replaced by an inductively coupled plasma processing apparatus.

The embodiments of the present disclosure further include the aspects described below.

### Appendix 1

A plasma processing apparatus, comprising:
a plasma processing chamber;
a variable impedance element;
a substrate support in the plasma processing chamber, the substrate support including
   a conductive base,
   an electrostatic chuck located on the conductive base and having a substrate support surface and a ring support surface,
   an edge ring located on the ring support surface to surround a substrate on the substrate support surface,
   a substrate bias electrode located below the substrate support surface inside the electrostatic chuck,
   a ring bias electrode located below the ring support surface inside the electrostatic chuck,
   an additional electrode located between the ring support surface and the ring bias electrode inside the electrostatic chuck and electrically coupled to a ground potential through the variable impedance element, and
   at least one connector electrically coupling the edge ring and the conductive base; and
at least one voltage pulse generator electrically coupled to the substrate bias electrode and the ring bias electrode to generate a pulsed voltage signal.

### Appendix 2

The plasma processing apparatus according to appendix 1, wherein
the at least one voltage pulse generator is electrically coupled to the substrate bias electrode and the ring bias electrode through the conductive base.

### Appendix 3

The plasma processing apparatus according to appendix 1 or appendix 2, wherein
the at least one voltage pulse generator includes
   a first voltage pulse generator electrically coupled to the substrate bias electrode to generate a first pulsed voltage signal, and
   a second voltage pulse generator electrically coupled to the ring bias electrode to generate a second pulsed voltage signal.

### Appendix 4

The plasma processing apparatus according to any one of appendixes 1 to 3, wherein
the substrate support includes a substrate chuck electrode, and
the substrate chuck electrode is located between the substrate bias electrode and the substrate support surface inside the electrostatic chuck.

### Appendix 5

The plasma processing apparatus according to any one of appendixes 1 to 4, wherein
the substrate support includes a ring chuck electrode, and
the ring chuck electrode is located between the ring support surface and the additional electrode inside the electrostatic chuck.

### Appendix 6

A plasma processing apparatus, comprising:
a plasma processing chamber;
a variable impedance element;
a substrate support in the plasma processing chamber, the substrate support including
   a conductive base,
   an electrostatic chuck located on the conductive base and having a substrate support surface and a ring support surface,
   an edge ring located on the ring support surface to surround a substrate on the substrate support surface,
   a substrate bias electrode located below the substrate support surface inside the electrostatic chuck,
   a ring bias electrode located below the ring support surface inside the electrostatic chuck,
   an additional electrode located between the ring support surface and the ring bias electrode inside the electrostatic chuck and electrically coupled to a ground potential through the variable impedance element, and
   at least one connector electrically coupling the edge ring and the conductive base; and
at least one radio-frequency generator electrically coupled to the substrate bias electrode and the ring bias electrode to generate a radio-frequency signal.

### Appendix 7

The plasma processing apparatus according to appendix 6, wherein
the at least one radio-frequency generator is electrically coupled to the substrate bias electrode and the ring bias electrode through the conductive base.

### Appendix 8

The plasma processing apparatus according to appendix 6 or appendix 7, wherein
the at least one radio-frequency generator includes
   a first radio-frequency generator electrically coupled to the substrate bias electrode, and
   a second radio-frequency generator electrically coupled to the ring bias electrode.

### Appendix 9

The plasma processing apparatus according to any one of appendixes 6 to 8, wherein
the substrate support includes a substrate chuck electrode, and
the substrate chuck electrode is located between the substrate bias electrode and the substrate support surface inside the electrostatic chuck.

### Appendix 10

The plasma processing apparatus according to any one of appendixes 6 to 9, wherein
the substrate support includes a ring chuck electrode, and
the ring chuck electrode is located between the ring support surface and the additional electrode inside the electrostatic chuck.

The above embodiments are mere examples described for illustrative purposes and are not intended to limit the scope of the present disclosure. The embodiments may be modified in various manners without departing from the spirit and scope of the present disclosure. For example, one or more components in one embodiment may be added to the structure according to another embodiment. One or more components in one embodiment may be replaced with the corresponding one or more components in another embodiment.

The technique according to one exemplary embodiment of the present disclosure adjusts the potential of the edge ring.

1. A plasma processing apparatus, comprising:
a plasma processing chamber;
a variable impedance element;
a substrate support in the plasma processing chamber, the substrate support including:
a conductive base,
an electrostatic chuck located on the conductive base and having a substrate support surface and a ring support surface,
an edge ring located on the ring support surface to surround a substrate on the substrate support surface,
a substrate bias electrode located below the substrate support surface inside the electrostatic chuck,
a ring bias electrode located below the ring support surface inside the electrostatic chuck,
an additional electrode located between the ring support surface and the ring bias electrode inside the electrostatic chuck and electrically coupled to a ground potential through the variable impedance element, and
at least one connector electrically coupling the edge ring and the conductive base; and
at least one voltage pulse generator electrically coupled to the substrate bias electrode and the ring bias electrode to generate a pulsed voltage signal.

2. The plasma processing apparatus according to claim 1, wherein
the at least one voltage pulse generator is electrically coupled to the substrate bias electrode and the ring bias electrode through the conductive base.

3. The plasma processing apparatus according to claim 1, wherein
the at least one voltage pulse generator includes:
a first voltage pulse generator electrically coupled to the substrate bias electrode to generate a first pulsed voltage signal, and
a second voltage pulse generator electrically coupled to the ring bias electrode to generate a second pulsed voltage signal.

4. The plasma processing apparatus according to claim 1, wherein
the substrate support includes a substrate chuck electrode, and
the substrate chuck electrode is located between the substrate bias electrode and the substrate support surface inside the electrostatic chuck.

5. The plasma processing apparatus according to claim 4, wherein
the substrate support includes a ring chuck electrode, and
the ring chuck electrode is located between the ring support surface and the additional electrode inside the electrostatic chuck.

6. A plasma processing apparatus, comprising:
a plasma processing chamber;
a variable impedance element;
a substrate support in the plasma processing chamber, the substrate support including:
a conductive base,
an electrostatic chuck located on the conductive base and having a substrate support surface and a ring support surface,
an edge ring located on the ring support surface to surround a substrate on the substrate support surface,
a substrate bias electrode located below the substrate support surface inside the electrostatic chuck,
a ring bias electrode located below the ring support surface inside the electrostatic chuck,
an additional electrode located between the ring support surface and the ring bias electrode inside the electrostatic chuck and electrically coupled to a ground potential through the variable impedance element, and
at least one connector electrically coupling the edge ring and the conductive base; and
at least one radio-frequency generator electrically coupled to the substrate bias electrode and the ring bias electrode to generate a radio-frequency signal.

7. The plasma processing apparatus according to claim 6, wherein
the at least one radio-frequency generator is electrically coupled to the substrate bias electrode and the ring bias electrode through the conductive base.

8. The plasma processing apparatus according to claim 6, wherein
the at least one radio-frequency generator includes
a first radio-frequency generator electrically coupled to the substrate bias electrode, and
a second radio-frequency generator electrically coupled to the ring bias electrode.

9. The plasma processing apparatus according to claim 6, wherein
the substrate support includes a substrate chuck electrode, and
the substrate chuck electrode is located between the substrate bias electrode and the substrate support surface inside the electrostatic chuck.

10. The plasma processing apparatus according to claim 9, wherein
the substrate support includes a ring chuck electrode, and
the ring chuck electrode is located between the ring support surface and the additional electrode inside the electrostatic chuck.
